(19) United States
(12) Patent Application Publication
(10) Pub. No.: US 2017/0002667 A1
(43) Pub. Date: Jan. 5, 2017

(54) HEAT-RESISTANT TURBINE BLADE MADE FROM OXIDE CERAMIC

(71) Applicant: Airbus Defence and Space GmbH, Taufkirchen (DE)

(72) Inventors: Juergen STEINWANDEL, Uhldingen-Muehlhofen (DE); Ning WANG, Munchen (DE); Helmut PIRINGER, Oberpframmern (DE)

(21) Appl. No.: 15/198,915

(22) Filed: Jun. 30, 2016

(30) Foreign Application Priority Data
Jul. 2, 2015 (EP) 15175008.0

(51) Int. Cl. F01D 5/28; B28B 11/24; C23C 16/30; B28B 1/24; C23C 16/442; C23C 16/04

(52) U.S. Cl. CPC F01D 5/282; C23C 16/442; C23C 16/045; C23C 16/30; B28B 1/24; B28B 11/243; F05D 2220/32; F05D 2230/90; F05D 2300/601; F05D 2300/44; F05D 2300/2118; F05D 2300/2112; F05D 2300/226; F05D 2300/228

(57) ABSTRACT

This relates to a turbine blade comprising a preformed fibrous fabric of fibres consisting of carbon, silicon carbide or rhenium fixed with a binder resin, and wherein the preformed and fixed fibrous fabric is coated and infiltrated, respectively, with B₄C, wherein the preformed fibrous fabric that has been fixed and coated and infiltrated, respectively, with B₄C further has a multilayer coating consisting of at least one layer of silicon carbide and at least one layer of a metal boride, a metal nitride or a metal carbide, and wherein an oxide ceramic is applied over the multilayer coating. The turbine blade is resistant to high temperatures and is particularly well suited for use in a gas turbine. Methods for producing the turbine blade are also described.

### CROSS-REFERENCE TO RELATED APPLICATION

This application claims priority to European Patent Application No. 15175008.0, filed Jul. 2, 2015, which is incorporated herein by reference in its entirety.

### TECHNICAL FIELD

The embodiments described herein relate to a turbine blade made from oxide ceramic. The present embodiment further relates to methods for manufacturing the turbine blade. The turbine blade made from oxide ceramic of the present embodiment is resistant to high temperatures and is suitable for use in a gas turbine, for example.

### BACKGROUND

The thermodynamic efficiency of gas turbines (Joule-Brayton cycle) is determined by the conditions before and after the compressor, particularly by the temperature difference. However, the range of usable compressor temperatures is not limitless, since they are raised by the subsequent combustion to such high temperature values that the materials presently available for gas turbines are no longer usable, even if a cooling system is employed. Typical maximum temperatures permissible for the co-based alloys presently used in gas turbine blades are about 1175° C.

Patent EP 0 863 221 describes turbine blades made from an investment casting material with a high chromium content. It is claimed that the turbine blades have improved thermal resistance.

DE 10 2004 011 151 describes turbine blades for which it is claimed that the thermal resistance is improved by a cooling system.

The need remains for turbine blades, particularly for a gas turbine, which demonstrate better resistance to high temperatures.

Coatings that increase the thermal resistance of a material are described in the prior art. For example, U.S. Pat. No. 8,137,802 describes coatings with ultra high temperature (UHT) resistance. These coating are applied over the surface of a space vehicle, for example, to withstand the temperatures encountered during re-entry. However, the coatings as such do not have the mechanical properties that are essential for turbine blades, in terms of breaking strength, for example.

U.S. Pat. No. 8,409,491 describes C—C composite materials with a UHT coating. These composite materials certainly have good thermal resistance, but they do not possess the mechanical properties that are essential for a turbine blade in a gas turbine, such as resistance to erosion when exposed to inlet gas at high speeds and pressures.

Besides the required improved thermal resistance, turbine blades should also have the mechanical strength, break resistance and erosion resistance that is indispensable for use in a gas turbine, where for example gas is introduced under high pressure and at high speed. Such tur-bines for use in a gas turbine must also be unaffected by oxidation even at high temperatures. The object of the present embodiment is to provide turbine blades of such kind.

### SUMMARY

The present embodiment relates to a turbine blade comprising a preformed fibrous fabric, that is to say a woven 2D and/or 3D moulded body of fibres consisting of carbon, silicon carbide or rhenium fixed with a binder resin, and wherein the preformed, fixed fibrous fabric is coated and/or infiltrated with B₄C, wherein the preformed fibrous fabric that has been fixed and coated or infiltrated with B₄C further has a multilayer coating consisting of at least one layer of silicon carbide and at least one layer consisting of a metal boride, a metal nitride or a metal carbide, and wherein an oxide ceramic is applied over the multilayer coating.

The turbine blade of the present embodiment is resistant to particularly high temperatures, above about 2000° C. up to about 2500° C. The turbine blade of the embodiment also possesses the mechanical strength and resistance to erosion necessary for turbine blades.

The present embodiment relates further to the use of the aforementioned turbine blade in a gas turbine.

The present embodiment also relates to a method for manufacturing the turbine blade, comprising the steps of: (a) Preparing a fibrous fabric, wherein the fibrous fabric is made from fibres consisting of carbon, silicon carbide or rhenium, and preforming and fixing the preformed fibrous fabric with a binder resin; (b) Coating and/or infiltrating the preformed and fixed fibrous fabric with B₄C; (c) Applying a multilayer coating to the preformed fibrous fabric which has been fixed and coated and/or infiltrated with B₄C, wherein the multilayer coating includes at least one silicon carbide layer and at least one layer consisting of a metal boride, a metal nitride or a metal carbide; and (d) Applying an oxide ceramic to the multilayer coating.

Further embodiments are described in the following description and the accompanying claims.

### DETAILED DESCRIPTION

In order to manufacture a turbine blade according to the embodiment, first a fibrous fabric is preformed and fixed in a manner suitable for the purpose. Heat-resistant fibres are used for this, particularly carbon fibres, silicon carbide fibres or rhenium fibres. The fibrous fabrics are preformed and fixed in a manner of which the principle is known in the prior art. For fixing, the binder resins known and usual in the prior art may be used, such as amino resin, polyurethane resin, methacrylate resin, phenol-formaldehyde resin, vinyl ester resin, polyester resin and epoxy resin. According to the embodiment, an amino resin is preferred, particularly a melamine formaldehyde resin such as Cassurite, a melamine formaldehyde resin produced by Clariant.

The preformed, fixed fibrous fabric is then coated and/or infiltrated with B₄C. For this, in theory any suitable coating process known in the related art may be used, such as the fluidised bed reactor (FBR) process, chemical vapour deposition (CVD), chemical vapour infiltration (CVI), or electrophoretic infiltration. According to the embodiment, use of the fluidised bed reactor (FBR) process is preferred. This is particularly effective for ensuring that all spaces in the fibrous fabric are closed up and the B₄C is applied as a homogenous, poreless layer, thereby preventing oxygen from reaching the fibres. In this context, according to the embodiment B₄C having an average grain size in the range from 0.1 to 20 μm is used. The weight increase attributable to the B₄C when the preformed and fixed fibrous fabric is coated and/or infiltrated therewith is preferably from about 5% by weight to about 15% by weight, more preferably about 10% by weight. A form-defining upper and/or lower sections of the fibrous fabric may be treated with B₄C separately and then assembled with each other. After the coating and/or infiltration with B₄C, thermal treatment may be carried out, preferably at about 2000° C.

According to the embodiment, a multilayer coating is also applied to the preformed fibrous fabric which has been fixed and coated and/or infiltrated with B₄C to better protect the fibrous fabric from penetration by oxygen and from high temperatures. The multilayer coating includes at least one silicon carbide layer and at least one layer consisting of a metal boride, a metal nitride or a metal carbide. The individual layers of the multilayer coating preferably have a layer thickness from 0.1 to 30 μm. The order of these layers in the multilayer coating is not of primary importance. However, according to the embodiment it is preferred if the uppermost layer of the multilayer coating is a silicon carbide layer, preferably having a layer thickness of 1-150 μm.

The metal boride, metal nitride or metal carbide for the corresponding layer of the multilayer coating is preferably selected from HfB₂, HfC, HfN, ZrB₂, ZrC, ZrN, TiB₂, TiC, TiN, TaB₂, TaC, TaN, NbC, TaC and NdB₂. According to the embodiment, ZrB₂ and/or HfB₂ are particularly preferred.

Methods for applying the multilayer coating are not subject to any special restrictions according to the embodiment. In principle, all suitable methods known from the related art are possible, such as a fluidised bed reactor (FBR) method, chemical vapour deposition (CVD), liquid silicon infiltration (LSI), pyrolysis (LPI), chemical vapour infiltration (CVI) or electrophoretic infiltration. According to the embodiment, application of the multilayer coating by chemical vapour deposition (CVD) is preferred.

According to the present embodiment, an oxide ceramic is also applied to the multilayer coating. This combination of the measures according to the embodiment serves to create a turbine blade not only with high thermal resistance, oxidation stability and resistance to breakage, but also with good mechanical strength and resistance to erosion, as is important for use in gas turbines.

For this purpose, according to the embodiment ceramic materials with high melting point are selected, particularly a melting point above 2000° C. Preferably, the ceramic material used for the oxide ceramic is selected from the following oxides: Al₂O₃, ZrO₂, MgO, Y₂O₃ and HfO₂ or mixtures thereof.

Oxides with higher melting points are preferred. Accordingly, oxides according to the embodiment are more preferably selected from ZrO₂, MgO, Y₂O₃ and HfO₂ or mixtures thereof. The use of ZrO₂ is particularly preferred according to the embodiment.

The method for applying the oxide ceramic to the fibrous fabric that has been pretreated according to the embodiment is not subject to any particular restrictions. In principle, any suitable method known from the related art may be considered. Typically, a slurry is prepared first by plastifying a powder of the oxidic ceramic material in water or an organic solvent and mixing and homogenising the mass yielded thereby. This may or may not be followed by a partial dehydration step. The mass obtained may be applied to the fibrous fabric that has been pretreated according to the embodiment for example by injection moulding in a casting mould containing the fibrous fabric that has been pretreated as the inlay core. The casting moulds typically consist of porous plastic having a pore size in the range from 12-22 μm and a water permeability of 10-28 l/min. Such plastics are commercially available, for example under the trade name Castimo resin. Alternatively, a sintered metal foam, e.g., aluminium foam, may be used for the casting mould.

Then, the injection moulded preform is dried, and a green body is obtained. The green body can be removed from the casting mould and worked mechanically as necessary. The possibly mechanically worked green body is then presintered. The sintering temperature is typically 70-80% of the melting temperature of the ceramic oxide, e.g., 1200° C.-2200° C. depending on the oxide. The cured ceramic obtained thereby may also be post-processed as necessary and desired.

Ultimately, a turbine blade is obtained that is not only resistant to high temperatures but also possesses good resistance to oxidation and break resistance, and which has the mechanical strength and erosion stability essential for use in gas turbines. The turbine blade of the present embodiment may therefore be used advantageously in gas turbines in which compressor temperatures higher than those currently achievable in the prior art are possible. For example, a turbine blade of the present embodiment may be used with compressor temperatures of 2000° C. or more, preferably at up to 2500° C. This in turn makes gas turbine with improved thermodynamic efficiency possible.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the embodiment in any way. Rather, the foregoing detailed description will provide those skilled in the art with a convenient road map for implementing an exemplary embodiment, it being understood that various changes may be made in the function and arrangement of elements described in an exemplary embodiment without departing from the scope of the embodiment as set forth in the appended claims and their legal equivalents.

1. A turbine blade comprising a preformed fibrous fabric of fibres comprising carbon, silicon carbide or rhenium fixed with a binder resin, and wherein the preformed and fixed fibrous fabric is coated and/or infiltrated with B₄C, wherein the preformed fibrous fabric that has been fixed and coated or infiltrated with B₄C further has a multilayer coating comprising at least one layer of silicon carbide and at least one layer consisting of a metal boride, a metal nitride or a metal carbide, and wherein an oxide ceramic is applied over the multilayer coating.

2. The turbine blade according to claim 1, wherein the oxide ceramic comprises an oxide selected from Al₂O₃, ZrO₂, MgO, Y₂O₃ and HfO₂.

3. The turbine blade according to claim 1, wherein the metal boride, metal nitride or metal carbide is selected from HfB₂, HfC, HfN, ZrB₂, ZrC, ZrN, TiB₂, TiC, TiN, TaB₂, TaC, TaN, NbC, TaC and NdB₂.

4. Use of the turbine blade according to claim 1 in a gas turbine.

5. A method for manufacturing a turbine blade, comprising the following steps:
providing a fibrous fabric, wherein the fibrous fabric is made from fibres comprising carbon, silicon carbide or rhenium, and preforming and fixing the preformed fibrous fabric with a binder resin;
coating and/or infiltrating the preformed and fixed fibrous fabric with B₄C;
applying a multilayer coating to the preformed fibrous fabric which has been fixed and coated and/or infiltrated with B₄C, wherein the multilayer coating includes at least one silicon carbide layer and at least one layer comprising a metal boride, a metal nitride or a metal carbide; and
applying an oxide ceramic to the multilayer coating.

6. The method according to claim 5, wherein the binder resin is selected from an amino resin, polyurethane resin, methacrylate resin, phenol-formaldehyde resin, vinyl ester resin, polyester resin and epoxy resin.

7. The method according to claim 5, wherein the coating and/or infiltration with B₄C is performed in a fluidised bed reactor (FBR) process, chemical vapour deposition (CVD), chemical vapour infiltration (CVI), or electrophoretic infiltration, and wherein the B₄C has a grain size in the range from 0.1 to 20 μm, and wherein a weight increase from about 5% by weight to about 15% by weight is achieved due to the coating and/or infiltration of the preformed and fixed fibrous fabric with the B₄C.

8. The method according to claim 5, wherein the metal boride, metal nitride or metal carbide of the multilayer coating is selected from HfB₂, HfC, HfN, ZrB₂, ZrC, ZrN, TiB₂, TiC, TiN, TaB₂, TaC, TaN, NbC, TaC and NdB₂.

9. The method according to claim 5, wherein the multilayer coating is applied by fluidised bed reactor (FBR) process, chemical vapour deposition (CVD), liquid silicon infiltration (LSI), pyrolysis (LPI), chemical vapour infiltration (CVI) or electrophoretic infiltration.

10. The method according to claim 5, wherein the individual layers of the multilayer coating have a layer thickness from 0.1 to 30 μm.

11. The method according to claim 5, wherein a topmost silicon carbide layer is applied to the multilayer coating, with a layer thickness from 1-150 μm.

12. The method according to claim 5, wherein the oxide ceramic comprises an oxide selected from Al₂O₃, ZrO₂, MgO, Y₂O₃ and HfO₂.

13. The method according to claim 5, wherein the oxide ceramic is applied by plastifying a powder of the oxidic ceramic material in water or an organic solvent, mixing and homogenising the mass yielded, applying the mass obtained to the multilayer coating of the preformed and fixed fibrous fabric by injection moulding in a casting mould, drying the blank obtained thereby and sintering the dried blank after removing it from the casting mould.
